(19) United States
(12) Patent Application Publication
(10) Pub. No.: US 2025/0096150 A1
(43) Pub. Date: Mar. 20, 2025

(54) ANTI-ELECTROMAGNETIC INTERFERENCE WAFER STRUCTURE

(71) Applicant: WALTON ADVANCED ENGINEERING INC., Kaohsiung (TW)

(72) Inventors: CHUN JUNG LIN, Kaohsiung (TW); RUEI TING GU, Kaohsiung (TW)

(21) Appl. No.: 18/368,217

(22) Filed: Sep. 14, 2023

(51) Int. Cl. H01L 23/552; H01L 21/48; H01L 21/768

(52) U.S. Cl. CPC H01L 23/552; H01L 21/486; H01L 21/76831

(57) ABSTRACT

The present application discloses an anti-electromagnetic interference wafer structure in the wafer processing stage; the anti-electromagnetic interference wafer structure comprises a digital processing unit area with a digital processing unit, an insulating layer, a conducting layer and a plurality of information connectivity points wherein the digital processing unit has a top surface on which the insulating layer and the information connectivity points are designed, the insulating layer has a top surface on which the conducting layer is coated, and the conducting layer is capable of absorbing electromagnetic interferences passed on to the conducting layer.

### BACKGROUND OF THE INVENTION

### Field of the Invention

The present disclosure relates to a wafer structure, particularly a structure in which a conducting layer is coated on a digital processing unit in the wafer processing stage for isolation of electromagnetic interferences stemming from an adjacent analog processing unit.

### Description of the Prior Art

In general, semiconductor devices are manufactured in complex front-end and back-end processes, each of which might involve in thousand steps. The front-end process refers to producing multiple dies arranged on a semiconductor wafer and exactly the same and including circuits to be electrically connected with active and passive components. Moreover, the back-end process refers to singulation of single dies on a manufactured wafer and encapsulation of dies for structural support and environmental isolation.

Semiconductor processes are aimed at manufacture of compact semiconductor devices which mean less power consumption typically, higher operation efficiency and effective mass-production. Moreover, a compact semiconductor device which occupies less space inside a small-size end product expectably is manufactured with high-density active and passive components miniaturized by improvement of the front-end process. The miniature semiconductor device packages are manufactured by improvement of electric connectivity and encapsulating materials in the back-end process.

Semiconductor processes are also aimed at manufacture of semiconductor devices with high operation efficiency which is embodied by active components operated at a high speed. In high-frequency applications, for example, RF (Radio Frequency) wireless communication, integrated passive components are frequently embedded into semiconductor devices. However, high-frequency electrical devices are apt to or influenced by outside Electromagnetic Interference (EMI) and Radio Frequency Interference (RFI), both of which interfere with electrical operation.

For most electronic components or systems, Electromagnetic Interference (EMI) is a serious and challenging issue. An electronic component or system should be provided with good anti-electromagnetic interference protection with which effective and safe operation is guaranteed because circuit performance of an electronic component or system is frequently interrupted, lowered or restricted by EMI.

There have been several patents related to Electromagnetic Interference (EMI) as follows:
U.S. Ser. No. 15/175,992 discloses a semiconductor package device and a method for manufacturing the same. In embodiments of U.S. Ser. No. 15/175,992, a semiconductor package device includes a carrier, a first antenna, a second antenna, a package body and a first shield: the carrier includes an antenna area and a component area; the first antenna is formed on the antenna area; the second antenna extends from the antenna area and over the first antenna; the second antenna is electrically connected to the first antenna; the package body includes a first portion covering the component area and a second portion covering the antenna area; the first shield is conformally formed on the first portion of the package body and exposes the second portion of the package body.
U.S. Ser. No. 13/493,576 discloses a wafer-level package including a shield connected to a plurality of conductive elements disposed on a silicon wafer. The conductive elements are arranged to individually enclose micro-structure elements located on the silicon wafer and within cavities formed by the conductive elements for better shielding performance. The shield and the conductive elements function as the EMI shield. A method to develop a wafer-level package comprises steps as follows: providing a semiconductor wafer with a plurality of sub-elements; arranging at least one micro-structure element in each of the sub-elements; electrically connecting the micro-structure elements to the semiconductor wafer; forming a plurality of conductive elements arranged on the semiconductor wafer and surrounding the micro-structure elements for development of a plurality of cavities in which the micro-structure elements are located; arranging a shield on the conductive elements to enclose the micro-structure elements in the cavities.
U.S. Ser. No. 15/674,218 discloses an integrated circuit device for protecting circuits from transient electrical events. An integrated circuit device includes a first bipolar junction transistor (BJT) and a second BJT cross-coupled with the first BJT and functioning as a first semiconductor-controlled rectifier (SCR), wherein the first BJT has a base connected to a collector of the second BJT and the second BJT has a base connected to an emitter or a collector of the first BJT. The integrated circuit device further includes a triggering device which comprises a first diode with a cathode electrically connected to the base of the first BJT. The integrated circuit device further includes a third BJT cross-coupled with the second BJT and functioning as a second SCR wherein the third BJT has a collector connected to the base of the second BJT and a base connected to the collector of the second BJT.

TW201608694 discloses a method for development of a radio frequency field effect transistor in an active layer of a semiconductor-on-insulator wafer. The semiconductor-on-insulator wafer has a buried insulator side and an active layer side. The method further comprises bonding a second wafer to the active layer side of the semiconductor-on-insulator wafer. The method further comprises development of a shield layer for the semiconductor device. The shield layer comprises an electrically conductive material. The method further comprises coupling the radio frequency field effect transistor to a circuit with a radio frequency component. The method further comprises singulating the radio frequency field effect transistor, the radio frequency component and the shield layer into a die. The shield layer is located between a substrate of the radio frequency component and the radio frequency field effect transistor.

However, the volume of a package completed in the back-end process during which the EMI issue is solved is getting bigger. Accordingly, how to subdue EMI of an end product in the front-end process for minimized changes in costs and the manufacturing process deserves to be considered by people skilled in the art.

### SUMMARY OF THE INVENTION

In virtue of the above problem, an anti-electromagnetic interference wafer structure provided in the present disclosure relies on a conducting layer replacing an anti-electromagnetic interference structure on a traditional wafer for cost reduction of an anti-electromagnetic interference structure.

Accordingly, the present disclosure is to offer an anti-electromagnetic interference wafer structure in which an insulating layer is constructed on a digital processing unit for fast creation of a conducting layer.

The present disclosure is to offer an anti-electromagnetic interference wafer structure in which a conducting layer and an insulating layer are penetrated by via holes for electric conduction with outside under the anti-electromagnetic interference condition.

The present disclosure is to offer an anti-electromagnetic interference wafer structure which depends on an insulating wall to avoid interferences stemming from a conducting layer and satisfies electric conduction demanded by a digital processing unit.

The present disclosure is to offer an anti-electromagnetic interference wafer structure in which an analog signal transmitter unit is integrated for reduction of a back-end package structure.

To this end, an anti-electromagnetic interference wafer structure is embodied according to the following technical solution. In the present disclosure, an anti-electromagnetic interference wafer structure in the wafer processing stage comprises a digital processing unit area with a digital processing unit, an insulating layer, a conducting layer and a plurality of information connectivity points wherein the digital processing unit has a top surface on which the insulating layer and the information connectivity points are designed, the insulating layer has a top surface on which the conducting layer is coated, and the conducting layer is capable of absorbing electromagnetic interferences passed on to the conducting layer.

The purposes and technical issues in the present disclosure are further embodied by referring to the following technical measures.

In the anti-electromagnetic interference wafer structure, the digital processing unit area comprises at least a grounding connection point for electric conduction between the grounding connection point and the digital processing unit.

In the anti-electromagnetic interference wafer structure, a plurality of information connectivity points and at least a grounding connection point are designed on a bottom surface of a substrate.

In the anti-electromagnetic interference wafer structure, the digital processing unit area comprises a plurality of via holes penetrating the conducting layer and the insulating layer.

The anti-electromagnetic interference wafer structure comprises an analog processing unit area having an analog processing unit characteristic of electric conduction with the digital processing unit.

In the anti-electromagnetic interference wafer structure, the digital processing unit area comprises a plurality of insulating walls, each of which is located at an interface of a via hole and the conducting layer.

In the anti-electromagnetic interference wafer structure, the analog processing unit area comprises an analog signal transmitter unit and an analog signal receiver unit, each of which is characteristic of electric conduction with the analog processing unit.

In the anti-electromagnetic interference wafer structure, the digital processing unit area comprises a plurality of electric connectivity areas filled inside the via holes for electric conduction between the electric connectivity areas and the information connectivity points of the digital processing unit area.

Compared with the prior art, an anti-electromagnetic interference wafer structure in the present disclosure is effective in: (1) cost reduction of an anti-electromagnetic interference structure by means of a conducting layer replacing an anti-electromagnetic interference structure on a traditional wafer; (2) fast construction of a conducting layer through an insulating layer coated on a digital processing unit; (3) integration of an analog signal transmitter unit for the reduced size of a back-end package structure.

### BRIEF DESCRIPTIONS OF THE DRAWINGS

FIG. 1 is the first schematic view of an anti-electromagnetic interference wafer structure in the first embodiment.

FIG. 2a is the second schematic view of an anti-electromagnetic interference wafer structure in the first embodiment.

FIG. 2b is the third schematic view of an anti-electromagnetic interference wafer structure in the first embodiment.

FIG. 3 is the first schematic view of an anti-electromagnetic interference wafer structure in the second embodiment.

FIG. 4 is the second schematic view of an anti-electromagnetic interference wafer structure in the second embodiment.

### DETAILED DESCRIPTIONS OF THE PREFERRED EMBODIMENTS

An anti-electromagnetic interference wafer structure is explained in the preferred embodiments for clear understanding of purposes, characteristics and effects of the present application.

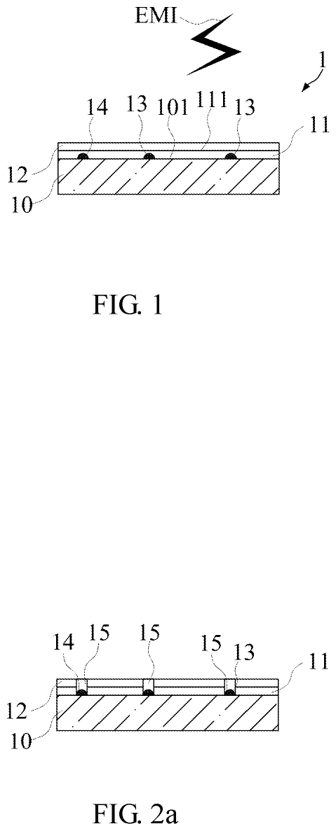

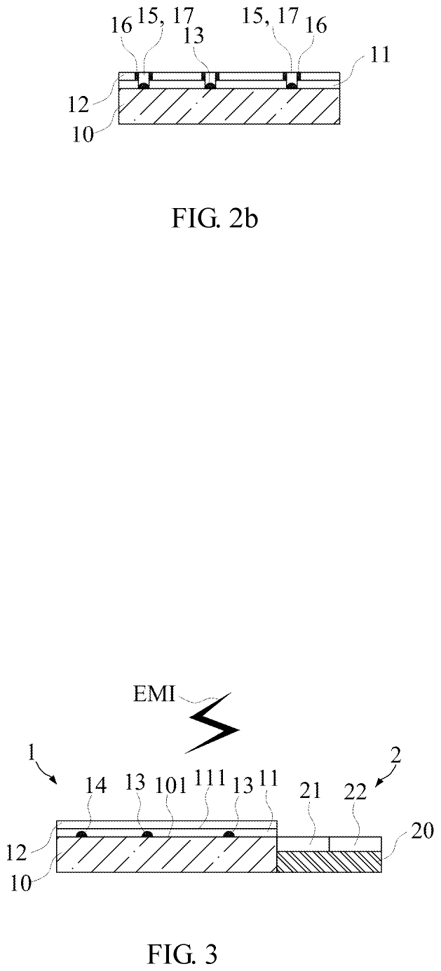

FIGS. 1, 2a and 2b illustrate an anti-electromagnetic interference wafer structure in the first embodiment. Referring to FIG. 1, which illustrates an anti-electromagnetic interference wafer structure comprises a digital processing unit area (1) with a digital processing unit (10), an insulating layer (11), a conducting layer (12) and a plurality of information connectivity points (13) wherein the digital processing unit (10) has a top surface (101) with the insulating layer (11) and the information connectivity points (13) arranged thereon and the insulating layer (11) has a top surface (111) with the conducting layer (12) coated thereon.

Specifically, the digital processing unit area (1) is effective in carrying and basically protecting the digital processing unit (10) and equipped with electrical input and output portions; the digital processing unit (10) which functions as Digital Signal Processing (DSP) is a unit to process digital signals particularly; the insulating layer (11) made of insulating materials functions as cutting off electric conduction and basically protecting the digital processing unit (10); the conducting layer (12), which comprises multiple materials developed in different phases of the semiconductor manufacturing process, is manufactured with any conductive material frequently, for example, fine metals including copper, tungsten or molybdenum, metal alloys or metal silicides, functions as preventing electromagnetic interference from outside or between top and bottom layers, and discharges waste heat to balance overall temperature and subdue temperature at a hot spot in the digital processing unit (10); the information connectivity points (13) are effective in providing electric connections between an electronic component and outside.

In practice, the digital processing unit area (10), as shown in FIG. 1, comprises at least a grounding connection point (14) which features electric conduction with the digital processing unit (1); the grounding connection point (14), which is the grounding line as a potential reference point for design of an electric circuit universally, provides a reference potential for a whole electric circuit, that is, 0V at the grounding connection point for a unified electrical potential of a whole electric circuit.

As shown in FIG. 2a, the digital processing unit area (10) in the previous description comprises a plurality of via holes (15) penetrating the conducting layer (12) as well as the insulating layer (11).

Specifically, the via holes (15) make the information connectivity points (13) and the grounding connection points (14) under the conducting layer (12) as well as the insulating layer (11) exposed to outside for the follow-up manufacturing process.

Referring to FIG. 2b, which illustrates the digital processing unit area (1) further comprises a plurality of insulating walls (16), each of which is located at an interface between a via hole (15) and the conducting layer (12);. In the embodiment, the digital processing unit area (1) comprises a plurality of electric connectivity areas (17) filled inside the via holes (15) for electric conduction between the electric connectivity areas (17) and the information connectivity points (13) of the digital processing unit areas (1).

In general, the insulating walls (16) function as preventing electric conduction between the conducting layer (12) and the electric connectivity areas (17) and guaranteeing no electric connectivity area (17) contacted by the conducting layer (12) directly; the electric connectivity areas (17) manufactured as gelatinoid substances with properties like adhesion and electric conduction, are cured after qualitative change but remain adhesive and electrically conductive.

Referring to FIG. 3, which illustrates an anti-electromagnetic interference wafer structure in the second embodiment. In the second embodiment, the main difference from the first embodiment is an analog processing unit area (2).

As shown in FIG. 3, an analog processing unit area (2), which is added at one side of a digital processing unit area (1), comprises an analog processing unit (20) characteristic of electric conduction with the digital processing unit (10). In the embodiment, the analog processing unit area (2) comprises an analog signal transmitter unit (21) and an analog signal receiver unit (22), each of which is characteristic of electric conduction with the analog processing unit (20).

Specifically, the analog processing unit area (2) is effective in carrying and basically protecting the analog processing unit (20) and equipped with electrical input and output portions; the analog processing unit (20), which functions as analog signal processing, that is, a method processing continuous analog signals effectively, is one unit to process analog signals specifically; the analog signal transmitter unit (21) is a basic output unit with which analog signals to be transmitted are emitted; the analog signal receiver unit (22) is a basic input unit with which analog signals to be transmitted are received.

In fact, each of the analog signal transmitter unit (21) and the analog signal receiver unit (22) imposes Electromagnetic Interference (EMI) to the digital processing unit (10). Accordingly, the conducting layer (12) in the present disclosure prevents interferences from outside and between top and bottom layers and features protection against electromagnetic interference for effective and safe operation of the digital processing unit (10).

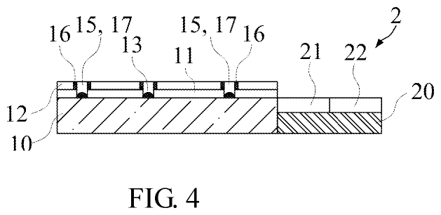

As shown in FIG. 4, the digital processing unit area (1) further comprises a plurality of insulating walls (16), each of which is located at an interface of a via hole (15) and the conducting layer (12). In the embodiment, the digital processing unit area (1) comprises a plurality of electric connectivity areas (17) filled inside the via holes (15) for electric conduction between the electric connectivity areas (17) and the information connectivity points (13) of the digital processing unit areas (1).

In summary, an anti-electromagnetic interference wafer structure in the present disclosure for anti-electromagnetic interference at the semiconductor wafer level rather than the package structure is different from ordinary wafer structures and referred to as creative work that meets patentability and is applied for the patent.

It should be reiterated that the above descriptions present the preferred embodiments of an anti-electromagnetic interference wafer structure and any equivalent changes or modifications in specifications, claims or drawings still belong to the technical field within the present disclosure with reference to claims hereinafter.

What is claimed is:

1. An anti-electromagnetic interference wafer structure in the wafer processing stage, comprising: a digital processing unit area with a digital processing unit, an insulating layer, a conducting layer and a plurality of information connectivity points wherein the digital processing unit has a top surface on which the insulating layer and the information connectivity points are designed, the insulating layer has a top surface on which the conducting layer is coated, and the conducting layer is capable of absorbing electromagnetic interferences passed on to the conducting layer.

2. The wafer structure as claimed in claim 1 wherein the digital processing unit area comprises at least a grounding connection point for electric conduction between the grounding connection point and the digital processing unit.

3. The wafer structure as claimed in claim 1 wherein the digital processing unit area comprises a plurality of via holes penetrating the conducting layer and the insulating layer.

4. The wafer structure as claimed in claim 1 which comprises an analog processing unit area having an analog processing unit characteristic of electric conduction with the digital processing unit.

5. The wafer structure as claimed in claim 3 wherein the digital processing unit area comprises a plurality of insulating walls, each of which is located at an interface of a via hole and the conducting layer.

6. The wafer structure as claimed in claim 4 wherein the analog processing unit area comprises an analog signal transmitter unit and an analog signal receiver unit, each of which is characteristic of electric conduction with the analog processing unit.

7. The wafer structure as claimed in claim 5 wherein the digital processing unit area comprises a plurality of electric connectivity areas filled inside the via holes for electric conduction between the electric connectivity areas and the information connectivity points of the digital processing unit area.
